(19) United States
(12) Patent Application Publication
(10) Pub. No.: US 2005/0217825 A1
(43) Pub. Date: Oct. 6, 2005

(54) Heat dissipating sheet and heat dissipating module made of the heat dissipating sheet

(76) Inventor: Lian-Huang Chern, Taipei (TW)

Correspondence Address: Lian-Huang Chern, 235 Chung-Ho, Box 8-24, Taipei, TW

(21) Appl. No.: 10/814,036

(22) Filed: Apr. 1, 2004

(51) Int. Cl. H05K 7/20

(52) U.S. Cl. 165/80.3; 165/185

(57) ABSTRACT

A heat dissipating sheet is a metal thin sheet. The heat dissipating sheet comprises a plurality of adjacent wave-like plates. Each wave-like plate is formed by a plurality of projections. Lower sides of all the wave-like plates are formed as a base surface. All the projections are protruded from the same side of the base surface. The projections of adjacent wave-like plates are alternatively arranged. Each wave-like plate is tightly connected to the adjacent wave-like plate so that heat can be transferred effectively. A plurality of heat dissipating sheets are assembled as a heat dissipating module as they are assembled on a heat conductive base and then are installed to a casing. The heat dissipating sheet and heat dissipating module with the heat dissipating sheets have preferred heat dissipating effect.

### FIELD OF THE INVENTION

The present invention relates to heat dissipating sheet device, and particular to a heat dissipating sheet and a heat dissipating module made of the heat dissipating sheets; wherein the heat dissipating sheet has a compact size so that it can be used to an electronic device. Thereby, the heat dissipating sheet has a large heat dissipating area to have preferred heat dissipating effect. Moreover, all projections are protruded from one side of the heat dissipating sheet so that only one machining process is necessary. The design of the projections is helpful to the airflow so as to dissipate more heat.

### BACKGSEMI-ROUND OF THE INVENTION

In the prior art, the heat dissipating device is formed by a plurality of flat sheets. The heat dissipating effect is not preferred due to finite heat dissipating area. Thereby, since the heat dissipating sheet is a flat sheet so that heat is only guided along the sheet surface and thus heat convention effect is bad. Moreover, the prior art heat dissipating sheet is made of aluminum alloy which is not a preferred heat conduction material and the structure of the heat dissipating sheet is not strong due to the material used.

To improve the defects in the prior art, some improvements are disclosed as shown in FIGS. 1 and 2. In the structure shown in FIGS. 1, and 2, the heat dissipating sheet is formed with a plurality of round holes 14 for dissipating heat and a plurality of trapezoidal projections 11 to 13. The projections are spaced and arranged in parallel. In some areas, the projections protrude from the same side of the heat dissipating sheet, but in other areas, the projections protrudes from another side of the heat dissipating sheets. In another improvement illustrated in FIGS. 3 to 5, it has similar structure as that disclosed in FIGS. 1 to 2, but the arrangements of the projections 11 to 14 are alternative as those illustrated in FIG. 5. Thereby, adjacent projections protrude from opposite sides of the heat dissipating sheet. Above mentioned heat generating elements are only used with heat transfer tubes, but can not be used in heat generating elements of electronic devices, such as chips or integrated circuits since the heat dissipating sheets can not tightly contact with the heat generating elements of electronic devices.

In above prior art, heat flows along the flat heat dissipating sheet so that the contact areas are confined and thus heat to be dissipated is also finite. Moreover, the projections are distributed at the two sides of the heat dissipating sheets so that two machining processes are necessary for punching the heat dissipating sheets, but this increase the cost in machining. Moreover, the projections protrude from two sides so that the heat dissipating sheet occupies a larger volume and thus only finite heat dissipating sheets are installed. As a result, the increment of heat dissipating area is confined, but this cannot conform the requirement of compact size of electronic devices.

### SUMMARY OF THE INVENTION

Accordingly, the primary object of the present invention is to provide a heat dissipating sheet and a heat dissipating module made of the heat dissipating sheets; wherein the heat dissipating sheet has a compact size so that it can be used to an electronic device. Thereby, the heat dissipating sheet has a large heat dissipating area so as to have preferred heat dissipating effect. Moreover, all projections are protruded from one side of the heat dissipating sheet so that only one machining process is necessary. The design of the projections is helpful to the airflow so as to dissipate more heat.

To achieve above objects, the present invention provides a heat dissipating sheet is a metal thin sheet. The heat dissipating sheet comprises a plurality of adjacent wave-like plates. Each wave-like plate is formed by a plurality of projections; lower sides of all the wave-like plates formed as a base surface. All the projections are protruded from the same side of the base surface. The projections of adjacent wave-like plates are alternatively arranged. Each wave-like plate is tightly connected to the adjacent wave-like plate so that heat can be transferred effectively. A plurality of heat dissipating sheets are assembled as a heat dissipating module as they are assembled on a heat conductive base and then are installed to a casing. The heat dissipating sheet and heat dissipating module with the heat dissipating sheets have preferred heat dissipating effect.

The various objects and advantages of the present invention will be more readily understood from the following detailed description when read in conjunction with the appended drawing.

### BRIEF DESCRIPTION OF THE DRAWINGS

FIG. 1 is an elevation view of the prior art heat dissipating sheet.

FIG. 2 is a lateral view of the heat dissipating sheet of FIG. 1.

FIG. 3 is an elevation view of the prior art heat dissipating sheet.

FIG. 4 is a lateral view of the heat dissipating sheet in FIG. 3.

FIG. 5 is a cross section view of the projection of the heat dissipating sheet in FIG. 3.

FIG. 6 is a perspective view of the heat dissipating sheet in the first embodiment of the present invention.

FIG. 7 is a cross section view along line A-A of FIG. 6.

FIG. 8 is a cross section view along line B-B of FIG. 6.

FIG. 9 is a partial elevation view of the heat dissipating sheet in FIG. 6.

FIGS. 10-12 are cross section views about the other embodiments of the heat dissipating sheet of the present invention.

FIG. 13 is a perspective view about a further embodiment of the heat dissipating sheet in the present invention.

FIG. 14 is an exploded view showing that the heat dissipating sheet of the present invention is used with a circuit board.

FIG. 15 is a cross section view of FIG. 14.

FIG. 16 is an exploded perspective view of the heat dissipating module of the present invention.

FIG. 17 is an exploded perspective view of another heat dissipating module of the present invention.

FIG. 18 is an exploded perspective view of a further heat dissipating module of the present invention.

FIG. 19 is a partial enlarged view of the application of the heat dissipating sheet of the present invention.

FIG. 20 is a partial enlarged view of another application of the heat dissipating sheet according to the present invention.

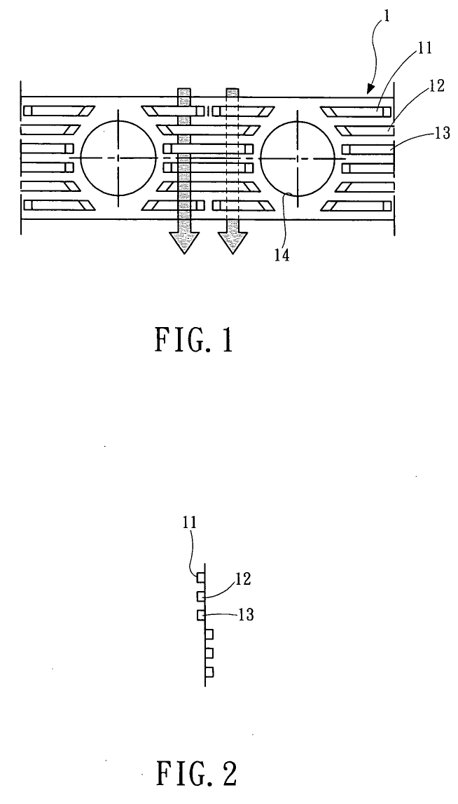

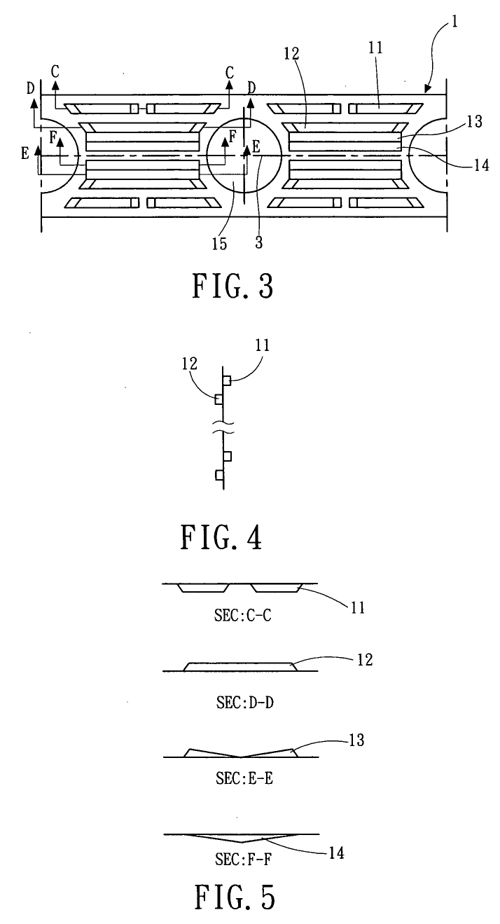

### DETAILED DESCRIPTION OF THE INVENTION

In order that those skilled in the art can further understand the present invention, a description will be described in the following in details. However, these descriptions and the appended drawings are only used to cause those skilled in the art to understand the objects, features, and characteristics of the present invention, but not to be used to confine the scope and spirit of the present invention defined in the appended claims.

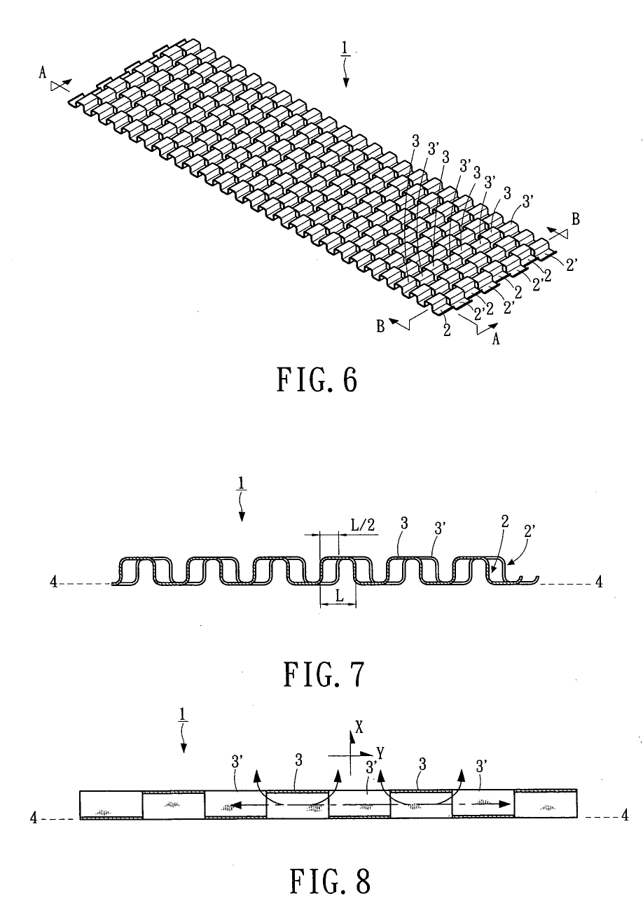

Referring to FIG. 6, a perspective view of the heat dissipating sheet 1 of the present invention is illustrated. The heat dissipating sheet 1 is a metal thin sheet formed by a plurality of wave-like plates 2, 2′. Each wave-like plate is formed by a plurality of projections 3, 3′ protruded from a base surface 4. All the projections 3, 3′ are protruded from the same side of the heat dissipating sheet 1. The projections 3, 3′ of adjacent wave-like plates 2, 2′ are alternatively arranged. Each wave-like plate 2 is tightly connected to the adjacent wave-like plate 2′ so that heat can be transferred effectively. The heat dissipating sheet 1 of the present invention has a larger area for dissipating heat so as to have a preferred heat dissipating effect.

With reference to FIG. 7, a cross section view along line A-A of FIG. 6, it is illustrated that each wave-like plate 2 is a length difference of half projection 3 from the adjacent wave-like plate 2′. The base surface of the heat dissipating sheet 1 is a horizontal surface for contacting a heat dissipating electronic element.

With reference to FIG. 8, it illustrates a drawing viewed from the line B-B of FIG. 6. It is shown that the two ends of each projection 3 is opened so that air can flow from one opening of the projection 3 and leave the projection 3 from another opening of the projection 3. Thereby, air can flow in the projection 3 successfully.

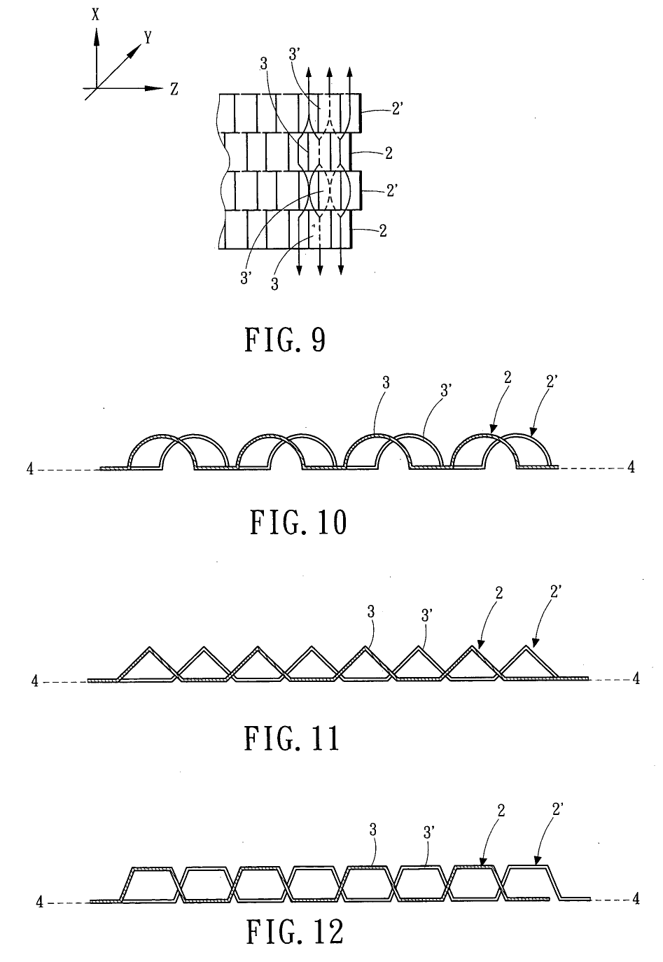

With reference to FIG. 9, the air path of the present invention is illustrated from the elevational view of FIG. 9. It is illustrated that the air has more contact area for dissipating heat in the projections.

Referring to FIG. 10, it is illustrated that the projection 3 can have a semi-round shape. FIG. 11 shows that the projection 3 has a triangular shape, and FIG. 12 shows that the projection 3 has a trapezoidal shape.

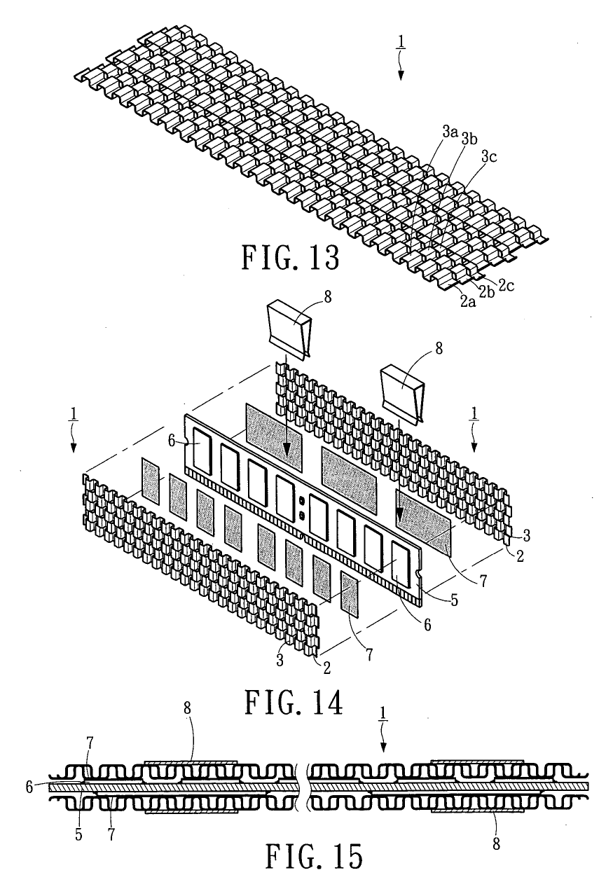

With reference to FIG. 13, it is illustrated that the widths of the projections 3a, 3b, 3c, 2a, 3b, 3c are different so that small projections have higher temperatures, and than the heat flows from projections of high temperatures to projections of low temperatures, and then heat is transferred by fan 20.

With reference to FIG. 14, an electronic device 5 has a plurality of heat generating elements 6. Two sides of the electronic device 6 are enclosed by two sheets of wave-like plates 2 with a plurality of projections 3. A sheet of heat conducting glue 7 is installed between the heat generating elements 6 and the wave-like plate 2. An elevational view of the FIG. 14 is shown in FIG. 15. Thereby, heat generated from the heat generating elements 6 will be dissipated through the heat conducting glue 7 to the wave-like plate 2 so as to be dissipated out. Thereby, in this embodiment, the heat conducting glue 7 can be neglected so that the wave-like plate 2 directly contacts the heat generating elements 6. Furthermore, in the present invention, two wave-like plates 2 can be connected to have U shape.

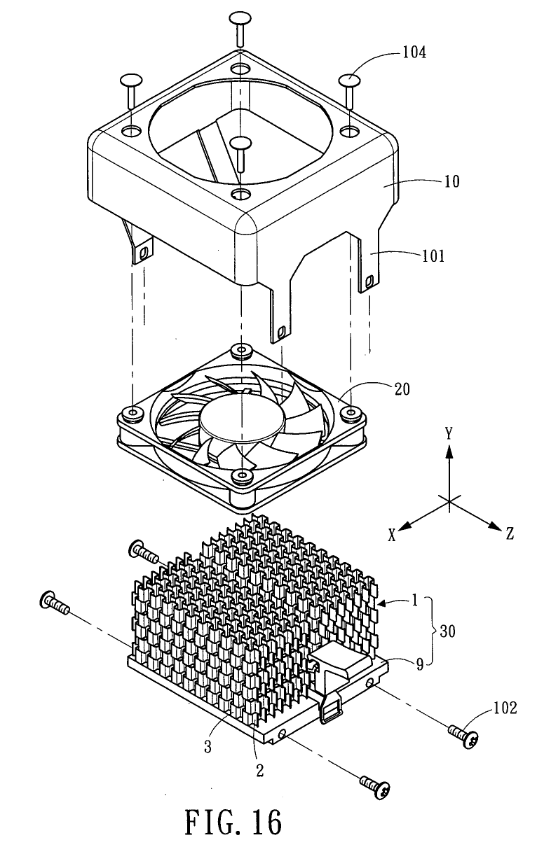

Referring to FIG. 16, the exploded perspective view of the heat dissipating module according to the present invention is illustrated. A heat dissipating module 30 includes a heat conductive base 9. A plurality of wave-like plates 2 are overlapped and are fixed on an upper surface of the heat conductive base 9 by heat conducting glue or welding. A plurality of screws 102 serve to lock the heat conductive base 9 to supporter 101 of a casing 10. A fan 20 is fixed to the casing 10 by rivets 104 so that the fan 20 is located above the plurality of wave-like plates 2. Furthermore, when the heat conductive base 9 directly contacts a center processing unit (CPU) (not shown). Heat generating from the CPU will transfer to the base 9 and then to the heat dissipating sheet 1 and to the fan 20. The heat dissipating effect of the present invention is preferred than that in the prior art.

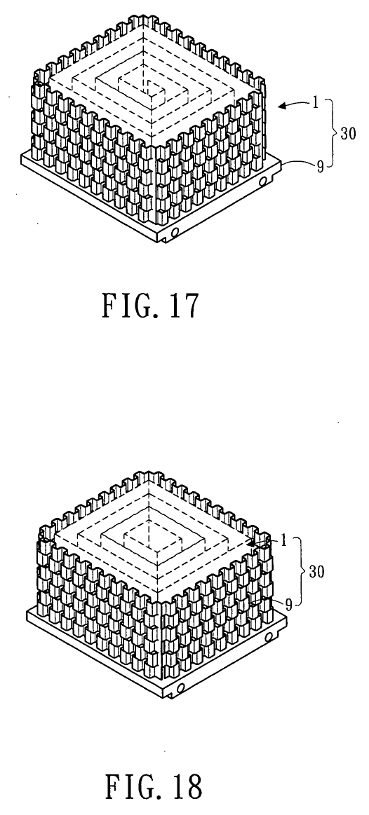

With reference to FIG. 17, in this embodiment, the heat dissipating sheet 1 having only one wave-like plate 2 is wound with a spiral shape and is located on the base 9. Referring to FIG. 18, this embodiment is similar to that in the FIG. 17, but the heat dissipating sheet 1 is formed by a plurality of wave-like plates 2.

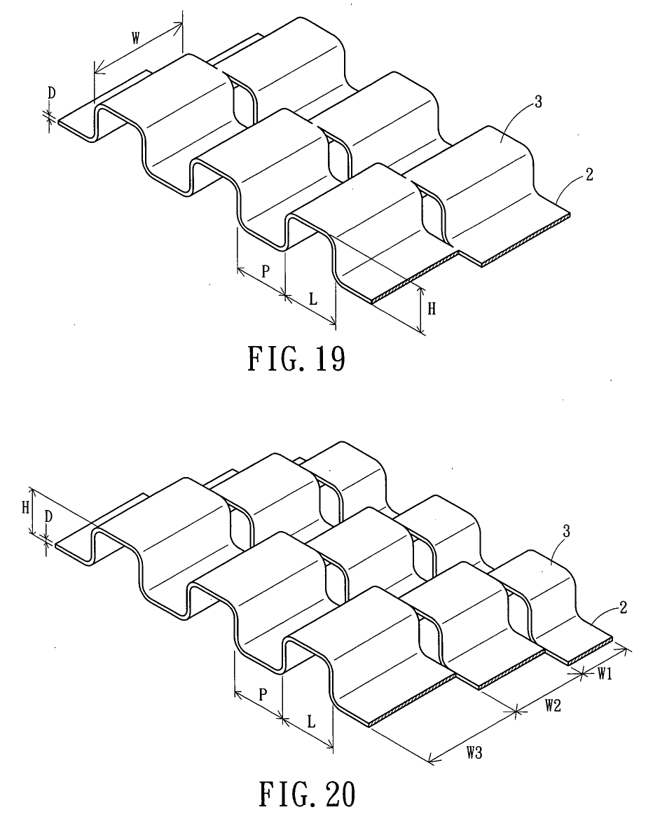

With reference to FIG. 19, one application of the present invention is illustrated. In this application, the projection 3 has a height H=1.6 mm, a length L=2.0 mm and a width of W=2.0 mm (it is also the width of the wave-like plate 2, and a thickness D=0.2 mm. Furthermore, the gap between two projections 3, 3′, P, is equal to 4.0 mm. The heat dissipating sheet 1 is made by copper.

In FIG. 20, the projection 3 has a height H=1.6 mm, a length L=2.0 mm, a width of W=1.0 mm, 2.0 mm and 3.0 mm; and a thickness D=0. 2 mm. Furthermore, the gap between two projections 3, 3′, P, is equal to 4.0 mm. The heat dissipating sheet 1 is made by copper.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. A heat dissipating sheet being a metal thin sheet; comprising:
a plurality of adjacent wave-like plates; each wave-like plate being formed by a plurality of projections; lower sides of all the wave-like plates formed as a base surface; all the projections being protruded from the same side of the base surface; the projections of adjacent wave-like plates being alternatively arranged; each wave-like plate being tightly connected to the adjacent wave-like plate so that heat can be transferred effectively.

2. The heat dissipating sheet as claimed in claim 1, wherein the metal thin sheet is made of copper.

3. The heat dissipating sheet as claimed in claim 1, wherein each projection has a rectangular shape.

4. The heat dissipating sheet as claimed in claim 1, wherein the projection has a semi-round shape.

5. The heat dissipating sheet as claimed in claim 1, wherein the projection has a triangular shape.

6. A heat dissipating module comprising:
a heat conductive base capable of being installed at heat generating elements of electronic devices; and
at least one heat dissipating sheet installed on the heat conductive base; each heat dissipating sheet being formed by a plurality of adjacent wave-like plates; each wave-like plate being formed by a plurality of projections; lower sides of all the wave-like plates formed as a base surface; all the projections being protruded from the same side of the base surface; the projections of adjacent wave-like plates being alternatively arranged; each wave-like plate being tightly connected to the adjacent wave-like plate so that heat can be transferred effectively;
wherein heat generated by the heat generating elements will transferred to the wave-like plates through the heat conductive base so as to be dissipated.

7. The heat dissipating sheet as claimed in claim 6, wherein there are a plurality of heat dissipating sheets and the heat dissipating sheets are spaced arranged in parallel.

8. The heat dissipating sheet as claimed in claim 6, wherein there is only one heat dissipating sheet which is formed with a spiral shape.

9. The heat dissipating sheet as claimed in claim 6, wherein there are a plurality of heat dissipating sheets which are arranged with a spiral shape.
